(19) United States
(12) Patent Application Publication
(10) Pub. No.: US 2019/0066980 A1
(43) Pub. Date: Feb. 28, 2019

(54) Ceramic Material Assembly For Use In Highly Corrosive Or Erosive Semiconductor Processing Applications

(71) Applicant: Component re-engineering company, Inc., Santa Clara, CA (US)

(72) Inventors: Brent Elliot, Cupertino, CA (US); Dennis George Rex, Williams, OR (US)

(21) Appl. No.: 15/927,940

(22) Filed: Mar. 21, 2018

Related U.S. Application Data
(60) Provisional application No. 62/474,597, filed on Mar. 21, 2017.

(51) Int. Cl. H01J 37/32; H01L 21/687; C23C 16/50; C23C 16/455

(52) U.S. Cl. CPC H01J 37/32495; H01L 21/68757; H01J 37/32642; H01J 2237/3321; C23C 16/50; C23C 16/45563; H01J 37/32467

(57) ABSTRACT

A composite assembly of a relatively inexpensive ceramic, such as alumina, with a skin, or covering, of a high wear ceramic, such as sapphire, adapted to be used in semiconductor processing environments subjected to high levels of corrosion and/or erosion. The design life of the composite assembly may be significantly longer than previously used components. The composite assembly may have its ceramic pieces joined together with aluminum, such that the joint is not vulnerable to corrosive aspects to which the composite assembly may be exposed.

### CROSS-REFERENCE TO RELATED APPLICATIONS

This application claims priority to U.S. Provisional Patent Application No. 62/474,597 to Elliot et al., filed Mar. 21, 2017, which is hereby incorporated by reference in its entirety.

### BACKGROUND

### Field of the Invention

This invention relates to corrosion resistant assemblies, namely ceramic assemblies with high wear materials on high wear surfaces.

### BRIEF DESCRIPTION OF THE DRAWINGS

FIGS. 1 is a drawing of a gas distribution ring around a wafer.

FIGS. 2 is a drawing of a gas injection nozzle.

FIGS. 3A is a drawing of the front portion of a gas injection nozzle according to some embodiments of the present invention.

FIGS. 3B is a drawing of the front portion of a gas injection nozzle according to some embodiments of the present invention.

FIGS. 3C is a drawing of the front portion of a gas injection nozzle according to some embodiments of the present invention.

FIG. 4A is a photograph of a focus ring.

FIGS. 4B is a focus ring according to some embodiments of the present invention.

FIGS. 4C is a focus ring according to some embodiments of the present invention.

FIG. 5A is a figure of an edge ring according to some embodiments of the present invention.

FIG. 5B is a partial cross-sectional view of an edge ring according to some embodiments of the present invention.

FIG. 6 is photograph of an alumina disc with a sapphire surface layer according to some embodiments of the present invention.

### SUMMARY

A composite assembly of a relatively inexpensive ceramic, such as alumina, with a skin, or covering, of a high wear ceramic, such as sapphire, adapted to be used in semiconductor processing environments subjected to high levels of corrosion and/or erosion. The design life of the composite assembly may be significantly longer than previously used components. The composite assembly may have its ceramic pieces joined together with aluminum, such that the joint is not vulnerable to corrosive aspects to which the composite assembly may be exposed.

### DETAILED DESCRIPTION

In semiconductor manufacturing, high-energy gas plasma, which is both corrosive and high temperature, is used to effect processing necessary in the making of integrated circuits. In many applications, components are used in the processing environment to contain and direct the plasma. Typically these components, commonly called edge rings, focus rings, gas rings, gas plates, blocker plates, etc., are made from quartz, silicon, alumina, or aluminum nitride. It is not uncommon for these components to have lifetimes measured in hours, as the erosion of the parts by the plasma causes process drift and contamination, requiring replacement of the components after short service times. In some applications, the plasma is injected into the processing environment by use of an array of ceramic nozzles. These nozzles are monolithic parts, with complex geometries, and with a small orifice on the order of 0.010″ diameter for controlling the flow rate and pattern of the plasma. Typical materials for these nozzles are aluminum oxide or aluminum nitride. Even with the use of these advanced ceramics, lifetime of the nozzles is 3 months due to erosion of the orifice by the high energy plasma. This requires that the machine be completely shut down every three months to replace the nozzle array, typically comprising more than 20 individual nozzles. While the nozzles are being eroded, they release contaminants into the plasma that reduce yields of the processing. And as the nozzles approach their end-of-life, the flow of the plasma begins to increase due to erosion of the orifice, which causes the process performance to change, further reducing yields. Other advanced ceramic materials have significantly lower erosion rates in that plasma environment, such as sapphire and yttrium oxide. If components such as edge rings and injector nozzles could be made with these materials, significant lifetime and performance improvements would result. However, the manufacturing and cost limitations mentioned above, limit the use of such materials for this application. What is needed is a method to utilize the properties of the best materials with a cost near that of the current materials.

Aspects of the current invention provide a method to combine the properties of the best materials for erosion and corrosion such as sapphire (mono-crystalline aluminum oxide), yttrium oxide, and partially-stabilized zirconium oxide (PSZ), with the lower cost advanced ceramic materials such as aluminum oxide. Utilizing methods according to embodiments of the present invention, which uses aluminum as a brazing material for joining advanced ceramic materials to themselves and other materials, it is now possible to join the properties of the highest performing advanced ceramic materials with the costs and manufacturability of the lower cost and simple manufacturability of ceramics such as alumina. Such processes produce joints with high levels of corrosion and erosion resistance, which can operate at elevated temperatures, and which can withstand significant variations in thermal expansion between the joined materials.

In some embodiments of the present invention, a protective surface layer is joined to the underlying structure in an area of high exposure to erosive elements. In some aspects, the surface layer is sapphire. In some aspects, the underlying structure is alumina. This allows for the use of a ceramic for the underlying structure which is much easier to produce, such as alumina.

The sapphire surface layer may be affixed to the underlying structure in any suitable manner. In one embodiment, the surface layer is attached to the underlying ceramic structure by a joining layer that is able to withstand corrosive processing chemistries. In one embodiment, the corrosive processing chemistries are related to fracking chemicals. In one embodiment, the joining layer is formed by a braze layer. In one embodiment, the braze layer is an aluminum brazing layer.

In one embodiment, a sapphire surface layer is joined to an underlying ceramic structure by a joining braze layer at any suitable temperature. In some aspects, the temperature is at least 770 C. In some aspects, the temperature is at least 800 C. In some aspects, the temperature is less than 1200 C. In some aspects, the temperature is between 770 C. and 1200 C. In some aspects, the temperature is between 800 C. and 1200 C. In some aspects, when using ceramics which may have material property degradation concerns at higher temperatures, the temperature used may be in the range of 770 C. to 1000 C.

In one embodiment, a sapphire surface layer is joined to an underlying ceramic structure by joining braze layer at any suitable temperature, including any of the temperatures disclosed herein, in a suitable environment. In some aspects, the environment is a nonoxygenated environment. In some aspects, the environment is free of oxygen. In some aspects, the environment is in the absence of oxygen. In some aspects, the environment is a vacuum. In some aspects, the environment is at a pressure lower than 1×10 E−4 Torr. In some aspects, the environment is at a pressure lower than 1×10 E−5 Torr. In some aspects, the environment is an argon (Ar) atmosphere. In some aspects, the environment is an atmosphere of other noble gasses. In some aspects, the environment is a hydrogen (H2) atmosphere.

In some aspects, a sapphire surface layer is joined to an underlying ceramic structure at any suitable temperature, including any of the temperatures disclosed herein, in a suitable environment, including any of the environments disclosed herein, by a braze layer. In some aspects, the braze layer is pure aluminum. In some aspects, the braze layer is metallic aluminum of greater than 89% by weight. In some aspects, the braze layer has more than 89% aluminum by weight. In some aspects, the braze layer is metallic aluminum of greater than 99% by weight. In some aspects, the braze layer has more than 99% aluminum by weight.

In some embodiments, a sapphire surface layer is joined to an underlying ceramic structure at any suitable temperature, including any of the temperatures disclosed herein, in a suitable environment, including any of the environments disclosed herein, by an aluminum joining layer, including an aluminum joining layer formed by any of the aluminum braze layers disclosed herein. In some aspects, the aluminum joining layer is free of diffusion bonding. In some aspects, there is no diffusion bonding between the sapphire layer and the aluminum joining layer. In some aspects, there is no diffusion bonding between the ceramic structure and the aluminum joining layer. In some aspects, the aluminum joining layer forms a hermetic seal between the sapphire surface layer and the ceramic structure. In some aspects, the aluminum joining layer forms a hermetic seal between the sapphire surface layer and the ceramic structure having a vacuum leak rate of <1×10 E−9 sccm He/sec. In some aspects, the aluminum joining layer is able to withstand corrosive processing chemistries. In some aspects, the corrosive processing chemistries are CVD related chemistries.

The underlying ceramic structure can be made from any suitable material, including aluminum nitride, aluminum oxide or alumina, sapphire, yttrium oxide, zirconia, and beryllium oxide.

As seen above, the thickness of the braze layer is adapted to be able to withstand the stresses due to the differential coefficients of thermal expansion between the various materials. Residual stresses may be incurred during the cool down from the brazing steps, which are described below. In addition, fast initial temperature ramping from room temperature may cause some temperature non-uniformity across the assembly, which may compound with the residual stresses incurred during brazing.

Aluminum has a property of forming a self-limiting layer of oxidized aluminum. This layer is generally homogenous, and, once formed, prevents or significantly limits additional oxygen or other oxidizing chemistries (such a fluorine chemistries) penetrating to the base aluminum and continuing the oxidation process. In this way, there is an initial brief period of oxidation or corrosion of the aluminum, which is then substantially stopped or slowed by the oxide (or fluoride) layer which has been formed on the surface of the aluminum. The braze material may be in the form of a foil sheet, a powder, a thin film, or be of any other form factor suitable for the brazing processes described herein. For example, the brazing layer may be a sheet having a thickness ranging from 0.00019 inches to 0.011 inches or more. In some embodiments, the braze material may be a sheet having a thickness of approximately 0.0012 inches. In some embodiments, the braze material may be a sheet having a thickness of approximately 0.006 inches. Typically, alloying constituents (such as magnesium, for example) in aluminum are formed as precipitates in between the grain boundaries of the aluminum. While they can reduce the oxidation resistance of the aluminum bonding layer, typically these precipitates do not form contiguous pathways through the aluminum, and thereby do not allow penetration of the oxidizing agents through the full aluminum layer, and thus leaving intact the self-limiting oxide-layer characteristic of aluminum which provides its corrosion resistance. In the embodiments using an aluminum alloy which contains constituents which can form precipitates, process parameters, including cooling protocols, would be adapted to minimize the precipitates in the grain boundary. For example, in one embodiment, the braze material may be aluminum having a purity of at least 99.5%. In some embodiments, a commercially available aluminum foil, which may have a purity of greater than 92%, may be used. In some embodiments, alloys are used. These alloys may include Al-5 w %Zr, Al-5 w %Ti, commercial alloys #7005, #5083, and #7075. These alloys may be used with a joining temperature of 1100 C. in some embodiments. These alloys may be used with a temperature between 800 C. and 1200 C. in some embodiments. These alloys may be used with a lower or higher temperature in some embodiments. In some aspects, the joining layer braze material may be aluminum of greater than 99% by weight. In some aspects, the joining layer braze material may be aluminum of greater than 98% by weight.

The joining methods according to some embodiments of the present invention rely on control of wetting and flow of the joining material relative to the ceramic pieces to be joined. In some embodiments, the absence of oxygen during the joining process allows for proper wetting without reactions which change the materials in the joint area. With proper wetting and flow of the joining material, a hermetically sealed joint can be attained at a low temperature relative to liquid phase sintering, for example.

The presence of a significant amount of oxygen or nitrogen during the brazing process may create reactions which interfere with full wetting of the joint interface area, which in turn may result in a joint that is not hermetic. Without full wetting, non-wetted areas are introduced into the final joint, in the joint interface area. When sufficient contiguous non-wetted areas are introduced, the hermeticity of the joint is lost.

In some embodiments, the joining process is performed in a process chamber adapted to provide very low pressures. Joining processes according to embodiments of the present invention may require an absence of oxygen in order to achieve a hermetically sealed joint. In some embodiments, the process is performed at a pressure lower than 1×10 E−4 Torr. In some embodiments, the process is performed at a pressure lower than 1×10 E−5 Torr.

The presence of nitrogen may lead to the nitrogen reacting with the molten aluminum to form aluminum nitride, and this reaction formation may interfere with the wetting of the joint interface area. Similarly, the presence of oxygen may lead to the oxygen reacting with the molten aluminum to form aluminum oxide, and this reaction formation may interfere with the wetting of the joint interface area. Using a vacuum atmosphere of pressure lower than 5×10−5 Torr has been shown to have removed enough oxygen and nitrogen to allow for fully robust wetting of the joint interface area, and hermetic joints. In some embodiments, use of higher pressures, including atmospheric pressure, but using non-oxidizing gasses such as hydrogen or pure noble gasses such as argon, for example, in the process chamber during the brazing step has also led to robust wetting of the joint interface area, and hermetic joints. In order to avoid the oxygen reaction referred to above, the amount of oxygen in the process chamber during the brazing process must be low enough such that the full wetting of the joint interface area is not adversely affected. In order to avoid the nitrogen reaction referred to above, the amount of nitrogen present in the process chamber during the brazing process must be low enough such that the full wetting of joint interface area is not adversely affected.

The selection of the proper atmosphere during the brazing process, coupled with maintaining a minimum joint thickness, may allow for the full wetting of the joint. Conversely, the selection of an improper atmosphere may lead to poor wetting, voids, and lead to a non-hermetic joint. The appropriate combination of controlled atmosphere and controlled joint thickness along with proper material selection and temperature during brazing allows for the joining of materials with hermetic joints.

In some aspects, the underlying structure ceramic is selected to present a close match in its coefficient of thermal expansion relative to the surface layer. Coefficients of thermal expansion may vary with temperature, so the selection of matching coefficients of thermal expansion should take into account the degree of match from room temperature, through the processing temperatures sought to be supported, and further through to the brazing temperature of the joining layer.

In an exemplary embodiment, the surface layer is sapphire, and the underlying structure is alumina. The coefficient of thermal expansion of sapphire (single crystal aluminum oxide) at 20 C. (293K), 517 C. (800K), and 1017 C. (1300K), respectively, is 5.38, 8.52, and 9.74×10E−6/K. The coefficient of thermal expansion of sintered alumina at 20 C., 500 C., and 1000 C., respectively, is 4.6, 7.1, and 8.1×10 E−6/K. These present a good match. In an exemplary embodiment, the brazing layer is aluminum with a purity of over 89%, and may be over 99% Al by weight.

The use of highly wear resistant surface layers, such as of sapphire, over an underlying structure of a more practical ceramic, such as alumina, provides a significant improvement over current approaches to components exposed to high wear erosive environments. The good thermal expansion match of sapphire to alumina affords a good pairing of materials.

The low temperature of the bonding process mentioned above enables use of Mg-PSZ, silicon nitride, and YTZ materials in addition to Sapphire. Current known process for bonding MgPSZ to other materials requires metallization at >1200 C. During these processes at a temperature at or above 1200 C., the toughening phase on the MgPSZ is degraded, with tetragonal zirconia forming cubic zirconia. Material is degraded by thermal overaging. A reason MgPSZ is a good material in high wear applications is due to the wear hardening effect of the abrasives on the material. As MgPSZ wears by abrasion, it develops a surface compressive stress from a phase transformation within the Zirconia. When scratched, the tetragonal zirconia collapses into monoclinic zirconia, and a volumetric expansion occurs in the Zirconia creating a compressive surface stress. This improves abrasion resistance of the ceramic. The processes according to the present invention may be only one that can bond MpPSZ to alumina without degrading the materials.

In some aspects, a method of designing and manufacturing components subjected to a highly erosive and/or highly corrosive operating environment includes utilizing hard materials such as advanced ceramics, metal-matrix-composites, and cermets in many industrial applications. The properties of these materials provide benefits in performance and lifetime in applications where corrosive, high temperature, and/or abrasive environments are present. However, another property of these materials is that in many cases they are difficult to join together. Typical methods currently in use to join these materials to themselves and to other materials include adhesives, glassing, active brazing, direct bonding, and diffusion bonding. All of these methods have limitations in either operating temperature, corrosion resistance, or joining materials of different thermal expansion coefficients. For example, adhesives cannot be used at elevated temperature, and have limited corrosion resistance. Active brazing has poor corrosion resistance; glasses have limited corrosion resistance and cannot tolerate any thermal expansion mismatch. Direct bonding and diffusion bonding also cannot tolerate any thermal expansion mismatch, as well as being expensive and difficult processes. Another characteristic of many of these materials is that they are difficult and costly to manufacture; by their very nature, they are extremely hard. Shaping them into required geometries can often require hundreds of hours of grinding with diamond tooling. Some of the strongest and hardest of these materials, for example sapphire and partially-stabilized zirconia (known as PSZ or ceramic steel), are so costly and difficult to work with that they have extremely limited industrial applications.

Utilizing this approach, the underlying alumina structure, to which the layer of PSZ is solidly joined, provides the dimensional stability required to achieve the necessary geometries. The PSZ provides the abrasion resistance performance where it is needed, and the manufacturability and costs of alumina are used to provide the bulk of the structure. Sapphire can also be used, although the cost increase of sapphire and the abrasion resistance of PSZ although make PSZ the better choice some cases. In other examples, components are made with tungsten carbide, an extremely hard ceramic material. Manufacturing such components is extremely expensive. Use of PSZ in locations shown to wear would increase component lifetime significantly, and use of alumina ceramic material in the component areas not subject to wear would substantially reduce the overall cost. This approach may be used with a component that was previously made entirely, or in substantial part, of a high wear material which may only be needed in limited areas. A component made entirely, or in substantial part, of a high wear material may bring high cost that can be lowered with the approach as described herein.

For example, with the gas plasma injection nozzles used in semiconductor manufacturing, a small piece of sapphire may be used to make the orifice. The rest of the nozzle may be manufactured in alumina or aluminum nitride utilizing the manufacturing methods and costs already in use—without the orifice. The sapphire orifice is then bonded in place utilizing the aluminum brazing process described herein. In this way, the plasma erosion resistance of the sapphire is coupled with the manufacturability and cost of the original alumina nozzle.

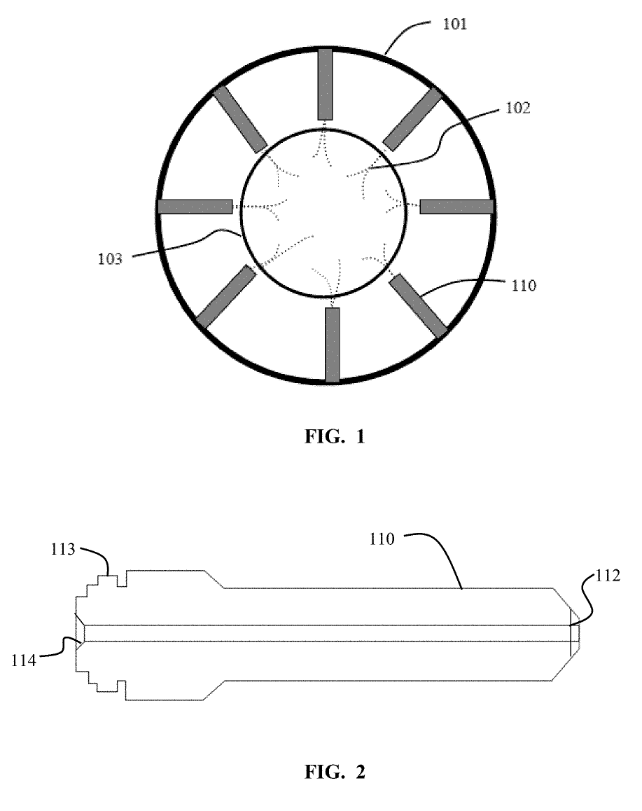

FIG. 1 illustrates a gas distribution ring 101 which is coupled to a plurality of CVD injector nozzles 110. The process is geared towards a substrate 103, which may be a semiconductor wafer. The outflow 102 from the injector nozzles 110 contributes to a processing of the substrate 103. FIG. 2 illustrates a CVD injector nozzle 110. The nozzle 110 has an interior passage 111 which ends at a passage exit 112 where the gas or other material which passes through the interior passage 111 exits the nozzle 110. The gas or other material enters the nozzle at a passage entrance 114. The injector nozzle 110 may have a mechanical interface 113 adapted to couple the injector nozzle 110 to the gas distribution ring 101.

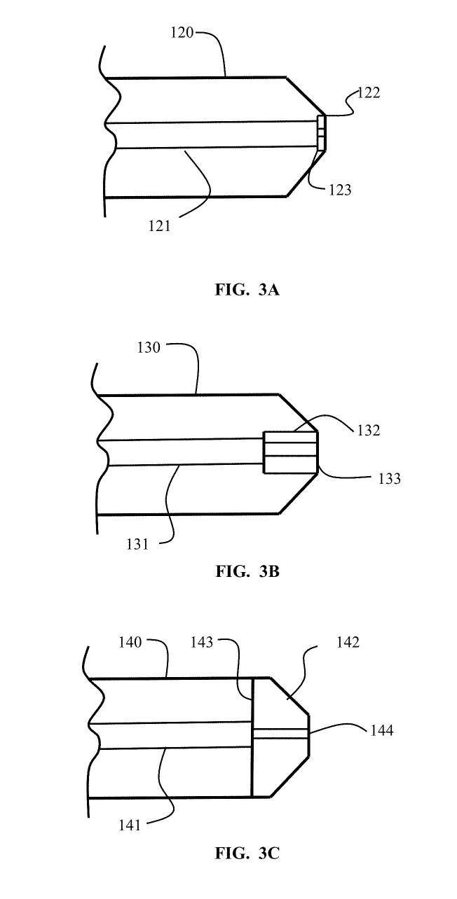

FIGS. 3A-C illustrates CVD injector nozzles according to some embodiments of the present invention. In some embodiments of the present invention, as seen in FIG. 3A, the fore end of a nozzle body 120 is seen with an interior passage 121. In some aspects, the nozzle body 120 is alumina. In some aspects, the nozzle body 120 is aluminum nitride. At the tip of the interior passage 121 there is disc 123 which resides in a counterbore at the front of the nozzle body 120. The disc 123 is a wear resistant material such as sapphire. The disc 123 may have an interior diameter which is less than the interior diameter of the interior passage 121. The disc 123 may be joined to the nozzle body 120 with a joining layer 122. The joining layer 122 may be of metallic aluminum. The disc 123 may be joined to the nozzle body 120 using a braze method described herein. The disc 123 may be joined to the nozzle body 120 with an aluminum braze layer 122 wherein there is no diffusion of the joining layer 122 into the nozzle body 120 or into the disc 123. In applications where the erosion of the nozzle occurs primarily at the tip of the nozzle, the use of the disc 123 comprising a wear resistant material, such as sapphire, allows for the use of a nozzle primarily manufactured from a low cost material, such as alumina, while gaining the benefit of the high wear and erosion resistance of a highly wear resistant material at an identified high wear area.

In some embodiments of the present invention, as seen in FIG. 3B, the fore end of a nozzle body 130 is seen with an interior passage 131. In some aspects, the nozzle body 130 is alumina. In some aspects, the nozzle body 130 is aluminum nitride. At the tip of the interior passage 131 there is an interior sleeve 133 which resides within an enlarged portion of the interior passage at the front of the nozzle body 130. The interior sleeve 133 is a wear resistant material such as sapphire. The interior sleeve 133 may have an interior diameter which is less than the interior diameter of the interior passage 131. The interior sleeve 133 may be joined to the nozzle body 130 with a joining layer 132. The joining layer 132 may be of metallic aluminum. The interior sleeve 133 may be joined to the nozzle body 130 using a braze method described herein. The interior sleeve 133 may be joined to the nozzle body 130 with an aluminum braze layer 132 wherein there is no diffusion of the joining layer 132 into the nozzle body 130 or into the interior sleeve 133. In applications where the erosion of the nozzle occurs primarily at the tip of the nozzle, the use of the interior sleeve 133 comprising a wear resistant material, such as sapphire, allows for the use of a nozzle primarily manufactured from a low cost material, such as alumina, while gaining the benefit of the high wear and erosion resistance of a highly wear resistant material at an identified high wear area.

In some embodiments of the present invention, as seen in FIG. 3C, the fore end of a nozzle body 140 is seen with an interior passage 141 which continues as a passage 144 through a wear tip 142. In some aspects, the nozzle body 140 is alumina. In some aspects, the nozzle body 140 is aluminum nitride. At the fore end of the nozzle body is a wear tip 142. The wear tip 142 is a wear resistant material such as sapphire. The wear tip 142 may have an interior diameter which is less than the interior diameter of the interior passage 141. The wear tip 142 may be joined to the nozzle body 140 with a joining layer 143. The joining layer 143 may be of metallic aluminum. The wear tip 142 may be joined to the nozzle body 140 using a braze method described herein. The wear tip 142 may be joined to the nozzle body 140 with an aluminum braze layer 143 wherein there is no diffusion of the joining layer 143 into the nozzle body 140 or into the wear tip 142. In applications where the erosion of the nozzle occurs primarily at the tip of the nozzle, the use of the wear tip 142 comprising a wear resistant material, such as sapphire, allows for the use of a nozzle primarily manufactured from a low cost material, such as alumina, while gaining the benefit of the high wear and erosion resistance of a highly wear resistant material at an identified high wear area.

In an exemplary embodiment, a semiconductor processing component which has portions of its exterior exposed to a high wear environment, such as plasma, which may have previously been subject to repeated replacement due to wear, is instead made with a wear surface layer on the portion or portions of its exterior exposed to a high wear environment. The semiconductor processing component may have its structural main body made of a ceramic which is easier to machine, such as alumina or aluminum nitride. The wear surface, or surfaces, may then have a high wear resistant surface layer, or skin, joined to the main body at these locations. The wear surface layer may be joined using metallic aluminum according to processes described herein. In some aspects, the main body may be undercut or otherwise taken down so that the outer surface of the wear surface layer, once joined, is at a same dimension of the main body up until that point. In aspects, the wear surface layer may be a single, unitary, piece. In some aspects, the wear surface layer may be comprised of a plurality of pieces which overlay each other, or have a labyrinth interface, or which abut each other.

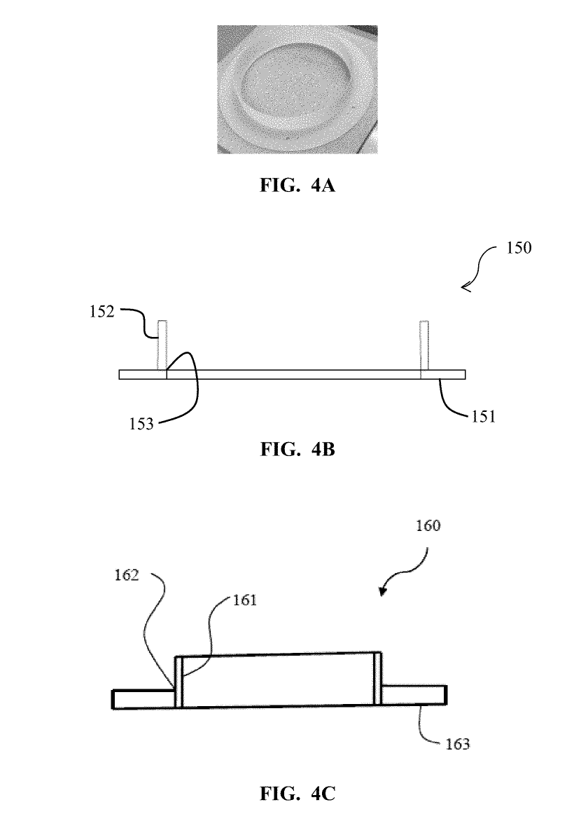

FIG. 4A is a photograph of a focus ring used in semiconductor processing. In some embodiments of the present invention, as seen in cross-section in FIG. 4B, a focus ring 150 with a collar 151 is joined to the top surface of a focus tube 152 with a joining layer 153. In some aspects, the collar 151 is alumina. In some aspects, the collar 151 is aluminum nitride. In some aspects, the focus tube 152 is sapphire.

In some embodiments of the present invention, as seen in FIG. 4C, a focus ring 160 has a focus ring structure 163 which is joined to a focus tube sleeve 161 with a joining layer 162 along its interior diameter. The focus tube sleeve 161 may be a cylindrical sleeve . In some aspects, the focus ring structure 163 is alumina. In some aspects, the focus ring structure 163 is aluminum nitride. In some aspects, the focus tube sleeve 131 is sapphire. In some aspects, the focus tube sleeve 131 is a unitary piece. In some aspects, the focus tube sleeve 131 is comprised of a plurality of pieces.

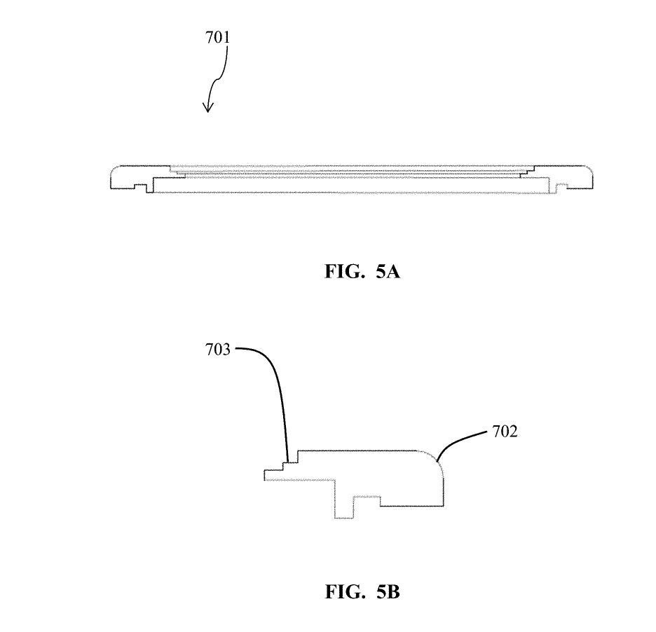

In some aspects, as seen in FIGS. 5A and 5B, an edge ring 701 adapted to ring a wafer during substrate processing may have wear surface layers 703, or skins, on a surface that is subject to wear, erosion, or other deleterious effects. The edge ring main support structure 702 may be of alumina, or aluminum nitride, or other appropriate ceramic, and the wear surface layer may be of sapphire. The wear surface layer may be joined to the main support structure with a joining layer of metallic aluminum as described herein. In some aspects, the main support structure 702 is aluminum nitride. In some aspects, the wear surface layers 703 are sapphire. In some aspects, the wear surface layers 703 are a unitary piece. In some aspects, the wear surface layers 703 are comprised of a plurality of pieces.

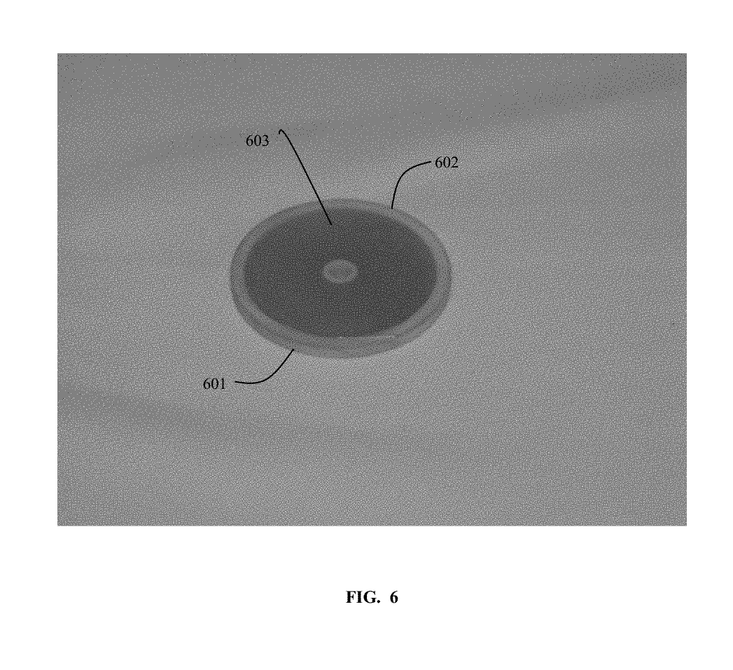

In an exemplary embodiment, as seen in FIG. 6, a 2 inch diameter disc of aluminum oxide 601 is seen with a sapphire surface layer 602. The disc has a hole through the center. A joining layer 603 is seen as the dark material, which is below the relatively clear top surface layer of sapphire. The gray aluminum oxide layer is seen through the top layer, as in this example the joining layer was not carried out to the edge of the aluminum oxide disc. The braze layer is metallic aluminum and is 0.002 inches thick. The brazing step was run at 850 C. for 30 minutes a pressure of less than 1×10 E−4 Torr. The skin wear surface layer is 0.010 inches thick.

As part of the design of components as described above, the thermal expansion differentials of the ceramics are reviewed. The thickness of the braze layer, and/or the thickness of the surface ceramic layer, may be selected to maintain stress levels during brazing and subsequent cooling, and during use, below allowable levels.

As evident from the above description, a wide variety of embodiments may be configured from the description given herein and additional advantages and modifications will readily occur to those skilled in the art. The invention in its broader aspects is, therefore, not limited to the specific details and illustrative examples shown and described. Accordingly, departures from such details may be made without departing from the spirit or scope of the applicant's general invention.

What is claimed is:

1. A semiconductor processing chamber component adapted for use in a highly erosive environment, said semiconductor processing chamber component comprising:
a structural support portion, said structural support portion having one or more identified high wear exposure surfaces;
one or more wear surface layers, said one or more wear surface layers joined to said one or more high wear exposure surfaces; and
one or more joining layers joining said structural support portion to said one or more wear surface layers,
wherein said joining layer comprises metallic aluminum.

2. The semiconductor processing chamber component of claim 1 wherein said structural support portion comprises alumina.

3. The semiconductor processing chamber component of claim 1 wherein said structural support portion comprises aluminum nitride.

4. The semiconductor processing component of claim 2 wherein said one or more surface layers comprise sapphire.

5. The semiconductor processing component of claim 3 wherein said one or more surface layers comprise sapphire.

6. The semiconductor processing component of claim 4 wherein said joining layer comprises metallic aluminum of greater than 99% by weight.

7. The semiconductor processing component of claim 5 wherein said joining layer comprises metallic aluminum of greater than 99% by weight.

8. The semiconductor processing component of claim 4 wherein said industrial component is an injector nozzle, and wherein said structural support portion comprises an interior passage.

9. The semiconductor processing component of claim 5 wherein said industrial component is an injector nozzle, and wherein said structural support portion comprises an interior passage.

10. The semiconductor processing component of claim 1 wherein said industrial component is a focus ring, and wherein said structural support portion comprises;
a collar; and
a focus tube;
and wherein said one or more wear surface layers are joined to an interior surface of said focus tube.

11. The semiconductor processing chamber component of claim 10 wherein said structural support portion comprises alumina.

12. The semiconductor processing chamber component of claim 10 wherein said structural support portion comprises aluminum nitride.

13. The semiconductor processing component of claim 11 wherein said one or more surface layers comprise sapphire.

14. The semiconductor processing component of claim 12 wherein said one or more surface layers comprise sapphire.

15. A focus ring adapted for use in a highly erosive environment, said semiconductor processing chamber component comprising:
a collar;
a focus tube; and
a joining layers joining said collar to said tube,
wherein said joining layer comprises metallic aluminum.

16. The focus ring of claim 15 wherein said collar comprises alumina.

17. The focus ring of claim 115 wherein said collar comprises aluminum nitride.

18. The focus ring of claim 16 wherein said focus tube comprises sapphire.

19. The focus ring of claim 17 wherein said focus tube comprises sapphire.

20. The semiconductor processing chamber component of claim 1 wherein said semiconductor processing chamber component is an edge ring adapted to support a wafer during processing.

21. The semiconductor processing chamber component of claim 20 wherein said structural support portion comprises alumina.

22. The semiconductor processing chamber component of claim 20 wherein said structural support portion comprises aluminum nitride.

23. The semiconductor processing component of claim 21 wherein said one or more surface layers comprise sapphire.

24. The semiconductor processing component of claim 22 wherein said one or more surface layers comprise sapphire.

25. A method for the manufacture of a semiconductor processing chamber component adapted for use in a highly erosive environment, said method comprising the steps of:
arranging one or more surface wear layers onto a semiconductor chamber processing component main support structure with one or more brazing layers disposed between said one or surface wear layers and said support structure, said brazing layer comprising metallic aluminum;
placing the pre-brazing sub assembly into a process chamber;
removing oxygen from said process chamber;
removing oxygen from said process chamber; and
joining said surface wear layers to said main support structure by heating to a temperature of above 770 C., thereby joining said surface wear layers to said main support structure with a hermetic joint.

26. The method of claim 25 wherein the step of removing oxygen from said process chamber comprises applying vacuum during the heating of the components to a pressure lower than 1×10 E−4.

27. The method of claim 26 wherein said main support structure comprises aluminum nitride.

28. The method of claim 26 wherein said main support structure comprises alumina.

29. The method of claim 27 wherein said one or more surface layers comprise sapphire.

30. The method of claim 28 wherein said one or more surface layers comprise sapphire.

31. The method of claim 25 wherein said brazing layer comprises metallic aluminum of greater than 99% by weight.

32. The method of claim 29 wherein said brazing layer comprises metallic aluminum of greater than 99% by weight.

33. The method of claim 30 wherein said brazing layer comprises metallic aluminum of greater than 99% by weight.

34. The method of claim 32 wherein said joining temperature is in the range of 770-1200 C.

35. The method of claim 33 wherein said joining temperature is in the range of 770-1200 C.
